(19) United States
(12) Patent Application Publication
(10) Pub. No.: US 2013/0047918 A1
(43) Pub. Date: Feb. 28, 2013

(54) DEPOSITION SYSTEMS INCLUDING A PRECURSOR GAS FURNACE WITHIN A REACTION CHAMBER, AND RELATED METHODS

(71) Applicants: Ronald Thomas Bertram, JR., Mesa, AZ (US); Michael Landis, Gilbert, AZ (US)

(72) Inventors: Ronald Thomas Bertram, JR., Mesa, AZ (US); Michael Landis, Gilbert, AZ (US)

(73) Assignee: SOITEC, Crolles Cedex (FR)

(21) Appl. No.: 13/591,761

(22) Filed: Aug. 22, 2012

Related U.S. Application Data
(60) Provisional application No. 61/526,143, filed on Aug. 22, 2011.

(51) Int. Cl. C30B 25/14; C30B 25/02

(52) U.S. Cl. 117/102; 118/725; 117/88

(57) ABSTRACT

Deposition systems include a reaction chamber, a substrate support structure disposed within the chamber for supporting a substrate within the reaction chamber, and a gas input system for injecting one or more precursor gases into the reaction chamber. The gas input system includes at least one precursor gas furnace disposed at least partially within the reaction chamber. Methods of depositing materials include separately flowing a first precursor gas and a second precursor gas into a reaction chamber, flowing the first precursor gas through at least one precursor gas flow path extending through at least one precursor gas furnace disposed within the reaction chamber, and, after heating the first precursor gas within the at least one precursor gas furnace, mixing the first and second precursor gases within the reaction chamber over a substrate.

### CROSS-REFERENCE TO RELATED APPLICATIONS

This application claims the benefit of U.S. Provisional Patent Application Ser. No. 61/526,143, filed Aug. 22, 2011, which is incorporated herein in its entirety by this reference. The subject matter of this application is related to the subject matter of U.S. patent application Ser. No. ______ (Attorney Docket No. 3356-10679.1US), which was filed on even date herewith in the name of Bertram et al. and entitled “DEPOSITION SYSTEMS HAVING ACCESS GATES AT DESIRABLE LOCATIONS, AND RELATED METHODS,” and to the subject matter of U.S. patent application Ser. No. ______ (Attorney Docket No. 3356-10708.1US), which was filed on even date herewith in the name of Bertram and entitled “DIRECT LIQUID INJECTION FOR HALIDE VAPOR PHASE EPITAXY SYSTEMS AND METHODS,” the entire disclosure of each of which application is incorporated herein in its entirety by this reference.

### FIELD

Embodiments of the invention generally relate to systems for depositing materials on substrates, and to methods of making and using such systems. More particularly, embodiments of the invention relate to hydride vapor phase epitaxy (HVPE) methods for depositing III-V semiconductor materials on substrates and to methods of making and using such systems.

### BACKGROUND

Chemical vapor deposition (CVD) is a chemical process that is used to deposit solid materials on substrates, and is commonly employed in the manufacture of semiconductor devices. In chemical vapor deposition processes, a substrate is exposed to one or more reagent gases, which react, decompose, or both react and decompose in a manner that results in the deposition of a solid material on the surface of the substrate.

One particular type of CVD process is referred to in the art as vapor phase epitaxy (VPE). In VPE processes, a substrate is exposed to one or more reagent vapors in a reaction chamber, which react, decompose, or both react and decompose in a manner that results in the epitaxial deposition of a solid material on the surface of the substrate. VPE processes are often used to deposit III-V semiconductor materials. When one of the reagent vapors in a VPE process comprises a hydride (or halide) vapor, the process may be referred to as a hydride vapor phase epitaxy (HVPE) process.

HVPE processes are used to form III-V semiconductor materials such as, for example, gallium nitride (GaN). In such processes, epitaxial growth of GaN on a substrate results from a vapor phase reaction between gallium chloride (GaCl) and ammonia (NH₃) that is carried out within a reaction chamber at elevated temperatures between about 500° C. and about 1,100° C. The NH₃ may be supplied from a standard source of NH₃ gas.

In some methods, the GaCl vapor is provided by passing hydrogen chloride (HCl) gas (which may be supplied from a standard source of HCl gas) over heated liquid gallium (Ga) to form GaCl in situ within the reaction chamber. The liquid gallium may be heated to a temperature of between about 750° C. and about 850° C. The GaCl and the NH₃ may be directed to (e.g., over) a surface of a heated substrate, such as a wafer of semiconductor material. U.S. Pat. No. 6,179,913, which issued Jan. 30, 2001 to Solomon et al., discloses a gas injection system for use in such systems and methods, the entire disclosure of which patent is incorporated herein by reference.

In such systems, it may be necessary to open the reaction chamber to atmosphere to replenish the source of liquid gallium. Furthermore, it may not be possible to clean the reaction chamber in situ in such systems.

To address such issues, methods and systems have been developed that utilize an external source of a GaCl₃ precursor, which is directly injected into the reaction chamber. Examples of such methods and systems are disclosed in, for example, U.S. Patent Application Publication No. 2009/0223442 A1, which published Sep. 10, 2009 in the name of Arena et al., the entire disclosure of which publication is incorporated herein by reference.

### BRIEF SUMMARY

This summary is provided to introduce a selection of concepts in a simplified form, such concepts being further described in the detailed description below of some example embodiments of the invention. This summary is not intended to identify key features or essential features of the claimed subject matter, nor is it intended to be used to limit the scope of the claimed subject matter.

In some embodiments, the present invention includes deposition systems that comprise an at least substantially enclosed reaction chamber, a susceptor disposed at least partially within the reaction chamber and configured to support a substrate within the reaction chamber, and a gas input system for injecting one or more precursor gases into the reaction chamber. The reaction chamber may be defined by a top wall, a bottom wall, and at least one side wall. The gas input system includes at least one precursor gas furnace disposed within the reaction chamber. At least one precursor gas flow path extends through the at least one precursor gas furnace.

In additional embodiments, the present invention includes methods of depositing semiconductor material. The methods may be performed using embodiments of deposition systems as describe herein. For example, some methods of embodiments of the disclosure may include separately flowing a group III element precursor gas and a group V element precursor gas into a reaction chamber, flowing the group III element precursor gas through at least one precursor gas flow path extending through at least one precursor gas furnace disposed within the reaction chamber to heat the group III element precursor gas, and after heating the group III element precursor gas within the at least one precursor gas furnace within the reaction chamber, mixing the group V element precursor gas and the group III element precursor gas within the reaction chamber over a substrate. A surface of the substrate may be exposed to the mixture of the group V element precursor gas and the group III element precursor gas to form a III-V semiconductor material on the surface of the substrate.

### BRIEF DESCRIPTION OF THE DRAWINGS

The present disclosure may be understood more fully by reference to the following detailed description of example embodiments, which are illustrated in the appended figures in which:

FIG. 1 is a cut-away perspective view schematically illustrating an example embodiment of a deposition system of the invention that includes a precursor gas furnace located within an interior region of a reaction chamber;

FIG. 2 is a cross-sectional side view illustrating the precursor gas furnace of FIG. 1, which includes a plurality of generally plate-shaped structures bonded together;

FIG. 3 is a top plan view of one of the generally plate-shaped structures of the precursor gas furnace of FIGS. 1 and 2;

FIG. 4 is a perspective view of the precursor gas furnace of FIGS. 1 and 2; and

FIG. 5 is a schematic diagram illustrating a plan view of another embodiment of a deposition system similar to that of FIG. 1 but including three precursor gas furnaces located within an interior region of a reaction chamber.

### DETAILED DESCRIPTION OF EMBODIMENTS OF THE INVENTION

The illustrations presented herein are not meant to be actual views of any particular system, component, or device, but are merely idealized representations that are employed to describe embodiments of the present invention.

As used herein, the term “III-V semiconductor material” means and includes any semiconductor material that is at least predominantly comprised of one or more elements from group IIIA of the periodic table (B, Al, Ga, In, and Ti) and one or more elements from group VA of the periodic table (N, P, As, Sb, and Bi). For example, III-V semiconductor materials include, but are not limited to, GaN, GaP, GaAs, InN, InP, InAs, AlN, AlP, AlAs, InGaN, InGaP, InGaNP, etc.

Improved gas injectors have recently been developed for use in methods and systems that utilize an external source of a GaCl₃ precursor that is injected into the reaction chamber, such as those disclosed in the aforementioned U.S. Patent Application Publication No. 2009/0223442 A1. Examples of such gas injectors are disclosed in, for example, U.S. Patent Application Ser. No. 61/157,112, which was filed on Mar. 3, 2009 in the name of Arena et al., the entire disclosure of which application is incorporated herein in its entirety by this reference. As used herein, the term “gas” includes gases (fluids that have neither independent shape nor volume) and vapors (gases that include diffused liquid or solid matter suspended therein), and the terms “gas” and “vapor” are used synonymously herein.

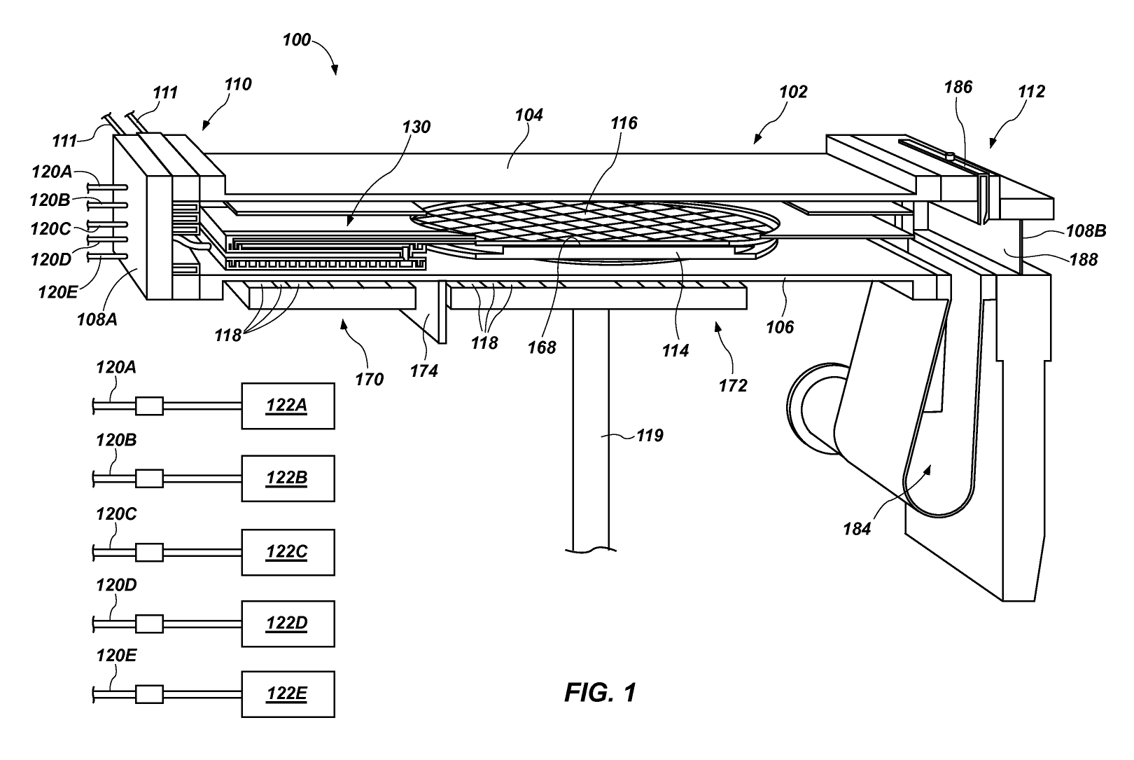

Embodiments of the present invention include, and make use of, deposition systems that include one or more precursor gas furnaces located within a reaction chamber. FIG. 1 illustrates a deposition system 100, which includes an at least substantially enclosed reaction chamber 102. In some embodiments, the deposition system 100 may comprise a CVD system, and may comprise a VPE deposition system (e.g., an HVPE deposition system).

The reaction chamber 102 may be defined by a top wall 104, a bottom wall 106, and one or more side walls. The side walls may be defined by one or more components of subassemblies of the deposition system. For example, a first side wall 108A may comprise a component of an injection subassembly 110 used for injecting one or more gases into the reaction chamber 102, and a second side wall 108B may comprise a component of a venting and loading subassembly 112 used for venting gases out from the reaction chamber 102 and for loading substrates into the reaction chamber 102 and unloading substrates from the reaction chamber 102.

The deposition system 100 includes a substrate support structure 114 (e.g., a susceptor) configured to support one or more workpiece substrates 116 on which it is desired to deposit or otherwise provide material within the deposition system 100. For example, the workpiece substrates 116 may comprise dies or wafers. The deposition system 100 further includes heating elements 118 (FIG. 1), which may be used to selectively heat the deposition system 100 such that an average temperature within the reaction chamber 102 may be controlled to within desirable elevated temperatures during deposition processes. The heating elements 118 may comprise, for example, resistive heating elements or radiant heating elements (e.g., heating lamps).

As shown in FIG. 1, the substrate support structure 114 may be mounted on a spindle 119, which may be coupled (e.g., directly structurally coupled, magnetically coupled, etc.) to a drive device (not shown), such as an electrical motor that is configured to drive rotation of the spindle 119 and, hence, the substrate support structure 114 within the reaction chamber 102.

In some embodiments, one or more of the top wall 104, the bottom wall 106, the substrate support structure 114, the spindle 119, and any other components within the reaction chamber 102 may be at least substantially comprised of a refractory ceramic material such as a ceramic oxide (e.g., silica (quartz), alumina, zirconia, etc.), a carbide (e.g., silicon carbide, boron carbide, etc.), or a nitride (e.g., silicon nitride, boron nitride, etc.). As a non-limiting example, the top wall 104, the bottom wall 106, the substrate support structure 114, and the spindle 119 may comprise transparent quartz so as to allow thermal energy radiated by the heating elements 118 to pass there through and heat gases within the reaction chamber 102.

The deposition system 100 further includes a gas flow system used to inject one or more gases into the reaction chamber 102 and to exhaust gases out from the reaction chamber 102. With continued reference to FIG. 1, the deposition system 100 may include five gas inflow conduits 120A-120E that carry gases from respective gas sources 122A-122E and into the injection subassembly 110. Optionally, gas flow control devices such as valves and/or mass flow controllers (not shown) may be used to selectively control the flow of gas through the gas inflow conduits 120A-120E, respectively.

In some embodiments, at least one of the gas sources 122A-122F may comprise an external source of at least one of GaCl₃, InCl₃, or AlCl₃, as described in U.S. Patent Application Publication No. 2009/0223442 A1. GaCl₃, InCl₃ and AlCl₃ may exist in the form of a dimer such as, for example, Ga₂Cl₆, In₂Cl₆ and Al₂Cl₆, respectively. Thus, at least one of the gas sources 122A-122F may comprise a dimer such as Ga₂Cl₆, In₂Cl₆ or Al₂Cl₆.

In embodiments in which one or more of the gas sources 122A-122E is or includes a GaCl₃ source, the GaCl₃ source include a reservoir of liquid GaCl₃ maintained at a temperature of at least 78° C. (e.g., approximately 130° C.), and may include physical means for enhancing the evaporation rate of the liquid GaCl₃. Such physical means may include, for example, a device configured to agitate the liquid GaCl₃, a device configured to spray the liquid GaCl₃, a device configured to flow carrier gas rapidly over the liquid GaCl₃, a device configured to bubble carrier gas through the liquid GaCl₃, a device, such as a piezoelectric device, configured to ultrasonically disperse the liquid GaCl₃, and the like. As a non-limiting example, a carrier gas, such as He, N₂, H₂, or Ar, may be bubbled through the liquid GaCl₃, while the liquid GaCl₃ is maintained at a temperature of at least 78° C., such that the source gas may include one or more carrier gases.

The flux of the GaCl₃ vapor through one or more of the gas inflow conduits 120A-120E may be controlled in some embodiments of the invention. For example, in embodiments in which a carrier gas is bubbled through liquid GaCl₃, the GaCl₃ flux from the gas source 122A-122E is dependent on one or more factors, including for example, the temperature of the GaCl₃, the pressure over the GaCl₃, and the flow of carrier gas that is bubbled through the GaCl₃. While the mass flux of GaCl₃ can in principle be controlled by any of these parameters, in some embodiments, the mass flux of GaCl₃ may be controlled by varying the flow of the carrier gas using a mass flow controller.

In some embodiments, the one or more of the gas sources 122A-122E may be capable of holding about 25 kg or more of GaCl₃, about 35 kg or more of GaCl₃, or even about 50 kg or more of GaCl₃. For example, the GaCl₃ source my be capable of holding between about 50 and 100 kg of GaCl₃ (e.g., between about 60 and 70 kg). Furthermore, multiple sources of GaCl₃ may be connected together to form a single one of the gas sources 122A-122E using a manifold to permit switching from one gas source to another without interrupting operation and/or use of the deposition system 100. The empty gas source may be removed and replaced with a new full source while the deposition system 100 remains operational.

In some embodiments, the temperatures of the gas inflow conduits 120A-120E may be controlled between the gas sources 122A-122E and the reaction chamber 102. The temperatures of the gas inflow conduits 120A-120E and associated mass flow sensors, controllers, and the like may increase gradually from a first temperature (e.g., about 78° C. or more) at the exit from the respective gas sources 122A-122E up to a second temperature (e.g., about 150° C. or less) at the point of entry into the reaction chamber 102 in order to prevent condensation of the gases (e.g., GaCl₃ vapor) in the gas inflow conduits 120A-120E. Optionally, the length of the gas inflow conduits 120A-120E between the respective gas sources 122A-122E and the reaction chamber 102 may be about eighteen feet or less, about twelve feet or less, or even about six feet or less. The pressure of the source gasses may be controlled using one or more pressure control systems.

In additional embodiments, the deposition system 100 may include less than five (e.g., one to four) gas inflow conduits and respective gas sources, or the deposition system 100 may include more than five (e.g., six, seven, etc.) gas inflow conduits and respective gas sources.

The one or more of the gas inflow conduits 120A-120E extend into the reaction chamber 102 through the injection subassembly 110. The injection subassembly 110 may comprise one or more blocks of material through which the gas inflow conduits 120A-120E extend. One or more fluid conduits 111 may extend through the blocks of material. A heat exchange fluid may be caused to flow through the one or more fluid conduits 111 so as to maintain the gas or gases flowing through the injection subassembly 110 by way of the gas inflow conduits 120A-120E within a desirable temperature range during operation of the deposition system 100. For example, it may be desirable to maintain the gas or gases flowing through the injection subassembly 110 by way of the gas inflow conduits 120A-120E at a temperature less than about 200° C. (150° C.) during operation of the deposition system.

One or more of the gas inflow conduits 120A-120E extends to a precursor gas furnace 130 disposed within the reaction chamber 102. In some embodiments, the precursor gas furnace 130 may be disposed at least substantially entirely within the reaction chamber 102.

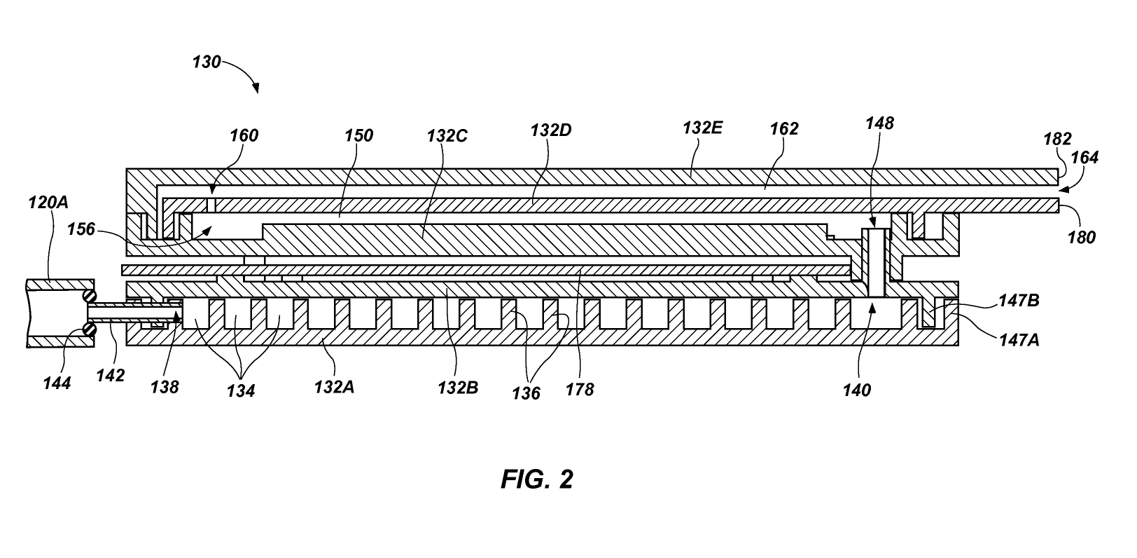

FIG. 2 is a cross-sectional side view of the precursor gas furnace 130 of FIG. 1. The furnace 130 of the embodiment of FIGS. 1 and 2 comprises five (5) generally plate-shaped structures 132A-132E that are attached together and are sized and configured to define one or more precursor gas flow paths extending through the furnace 130 in chambers defined between the generally plate-shaped structures 132A-132E. The generally plate-shaped structures 132A-132E may comprise, for example, transparent quartz so as to allow thermal energy radiated by the heating elements 118 to pass through the structures 132A-132E and heat precursor gas or gases in the furnace 130.

As shown in FIG. 2, the first plate-shaped structure 132A and the second plate-shaped structure 132B may be coupled together to define a chamber 134 therebetween. A plurality of integral ridge-shaped protrusions 136 on the first plate-shaped structure 132A may subdivide the chamber 134 into one or more flow paths extending from an inlet 138 into the chamber 134 to an outlet 140 from the chamber 134.

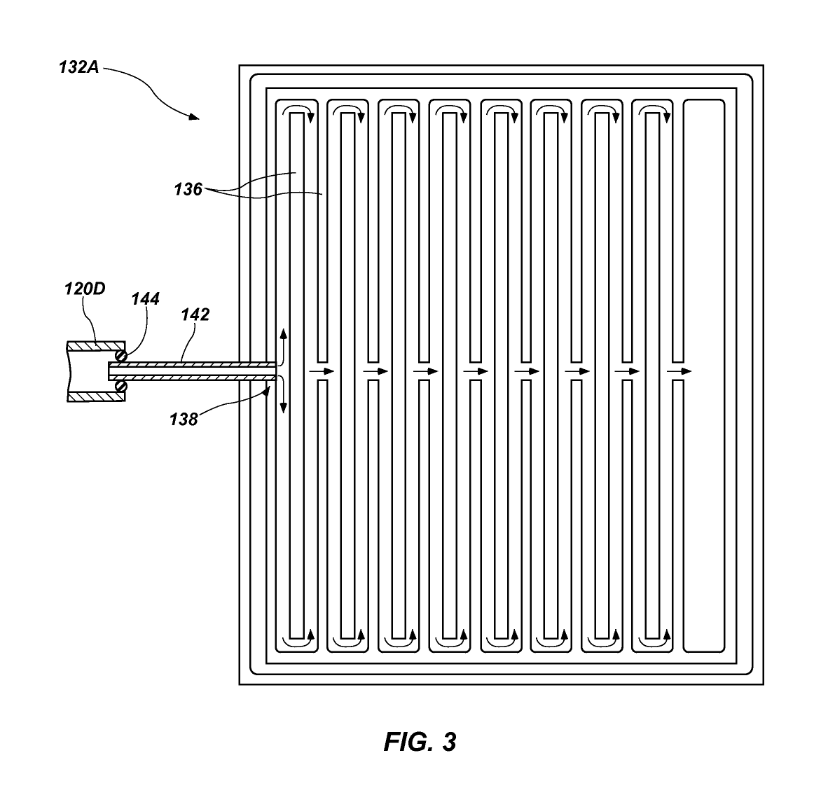

FIG. 3 is a top plan view of the first plate-shaped structure 132 and illustrates the ridge-shaped protrusions 136 thereon and the flow paths that are defined in the chamber 134 thereby. As shown in FIG. 3, the protrusions 136 define sections of the flowpath extending through the furnace 130 (FIG. 2) that have a serpentine configuration. The protrusions 136 may comprise alternating walls having apertures 138 therethough at the lateral ends of the protrusions 136 and at the center of the protrusions 136, as shown in FIG. 3. Thus, in this configuration, gases may enter the chamber 134 proximate a central region of the chamber 134 as shown in FIG. 3, flow laterally outward toward the lateral sides of the furnace 130, through apertures 138 at the lateral ends of one of the protrusions 136, back toward the central region of the chamber 134, and through another aperture 138 at the center of another protrusion 136. This flow pattern is repeated until the gases reach an opposing side of the plate 132A from the inlet 138 after flowing through the chamber 134 back and forth in a serpentine manner.

By causing one or more precursor gases to flow through this section of the flow path extending through the furnace 130, the residence time of the one or more precursor gases within the furnace 130 may be selectively increased.

Referring again to FIG. 2, the inlet 138 leading into the chamber 134 may be defined by, for example, a tubular member 142. One of the gas inflow conduits 120A-120E, such as the gas inflow conduit 120B, may extend to and couple with the tubular member 142, as shown in FIG. 1. A seal member 144, such as a polymeric O-ring, may be used to form a gas-tight seal between the gas inflow conduit 120B and the tubular member 142. The tubular member 142 may comprise, for example, opaque quartz material so as to prevent thermal energy emitted from the heating elements 118 from heating the seal member 144 to elevated temperatures that might cause degradation of the seal member 144. Additionally, the cooling of the injection subassembly 110 using flow of cooling fluid through the fluid conduits 111 may prevent excessive heating and resulting degradation of the seal member 144. By maintaining the temperature of the seal member 144 below about 200° C., an adequate seal may be maintained between one of the gas inflow conduits 120A-120E and the tubular member 142 using the seal member 144 when the gas inflow conduits comprises a metal or metal alloy (e.g., steel) and the tubular member 142 comprises a refractory material such as quartz. The tubular member 142 and the first plate-shaped structure 132A may be bonded together so as to form a unitary, integral quartz body.

As shown in FIGS. 2 and 3, the plate-shaped structures 132A, 132B may include complementary sealing features 147A, 147B (e.g., a ridge and a corresponding recess) that extend about the periphery of the plate-shaped structures 132A, 132B and at least substantially hermetically seal the chamber 134 between the plate-shaped structures 132A, 132B. Thus, gases within the chamber 134 are prevented from flowing laterally out from the chamber 134, and are forced to flow from the chamber 134 through the outlet 140 (FIG. 2).

Optionally, the protrusions 136 may be configured to have a height that is slightly less than a distance separating the surface 152 of the first plate-shaped structure 132A from which the protrusions 136 extend and the opposing surface 154 of the second plate-shaped structure 132B. Thus, a small gap may be provided between the protrusions 136 and the surface 154 of the second plate-shaped structure 132B. Although a minor amount of gas may leak through these gaps, this small amount of leakage will not detrimentally affect the average residence time for the precursor gas molecules within the chamber 134. By configuring the protrusions 136 in this manner, variations in the height of the protrusions 136 that arise due to tolerances in the manufacturing processes used to form the plate-shaped structures 132A, 132B can be accounted for, such that protrusions 136 that are inadvertently fabricated to have excessive height do not prevent the formation of an adequate seal between the plate-shaped structures 132A, 132B by the complementary sealing features 147A, 147B.

As shown in FIG. 2, the outlet 140 from the chamber 134 between the plate-shaped structures 132A, 132B leads to an inlet 148 to a chamber 150 between the third plate-shaped structure 132C and the fourth plate-shaped structure 132D. The chamber 150 may be configured such that the gas or gases therein flow from the inlet 148 toward an outlet 156 from the chamber 150 in a generally linear manner. For example, the chamber 150 may have a cross-sectional shape that is generally rectangular and uniform in size between the inlet 148 and the outlet 156. Thus, the chamber 150 may be configured to render the flow of gas or gases more laminar, as opposed to turbulent.

The plate-shaped structures 132C, 132D may include complementary sealing features 158A, 158B (e.g., a ridge and a corresponding recess) that extend about the periphery of the plate-shaped structures 132C, 132D and at least substantially hermetically seal the chamber 150 between the plate-shaped structures 132C, 132D. Thus, gases within the chamber 150 are prevented from flowing laterally out from the chamber 150, and are forced to flow from the chamber 150 through the outlet 156.

The outlet 156 may comprise, for example, an elongated aperture (e.g., a slot) extending through the plate-shaped structure 132D proximate an opposing end thereof from the end that is proximate the inlet 148.

With continued reference to FIG. 2, the outlet 156 from the chamber 150 between the plate-shaped structures 132C, 132D leads to an inlet 160 to a chamber 162 between the fourth plate-shaped structure 132D and the fifth plate-shaped structure 132E. The chamber 162 may be configured such that the gas or gases therein flow from the inlet 160 toward an outlet 164 from the chamber 162 in a generally linear manner. For example, the chamber 162 may have a cross-sectional shape that is generally rectangular and uniform in size between the inlet 160 and the outlet 164. Thus, the chamber 162 may be configured to render the flow of gas or gases more laminar, as opposed to turbulent, in a manner like that previously described with reference to the chamber 150.

The plate-shaped structures 132D, 132E may include complementary sealing features (e.g., a ridge and a corresponding recess) that extend about a portion of the periphery of the plate-shaped structures 132D, 132E and seal the chamber 162 between the plate-shaped structures 132D, 132E on all but one side of the plate-shaped structures 132D, 132E. A gap is provided between the plate-shaped structures 132D, 132E on the side thereof opposite the inlet 160, which gap defines the outlet 164 from the chamber 162. Thus, gases enter the chamber 162 through the inlet 160, flow through the chamber 162 toward the outlet 164 (while being prevented from flowing laterally out from the chamber 162 by the complementary sealing features 166A, 166B), and flow out from the chamber 162 through the outlet 164. The sections of the gas flow path or paths within the furnace 130 that are defined by the chamber 150 and the chamber 162 are configured to impart laminar flow to the one or more precursor gases caused to flow through the flow path or paths within the furnace 130, and reduce any turbulence therein.

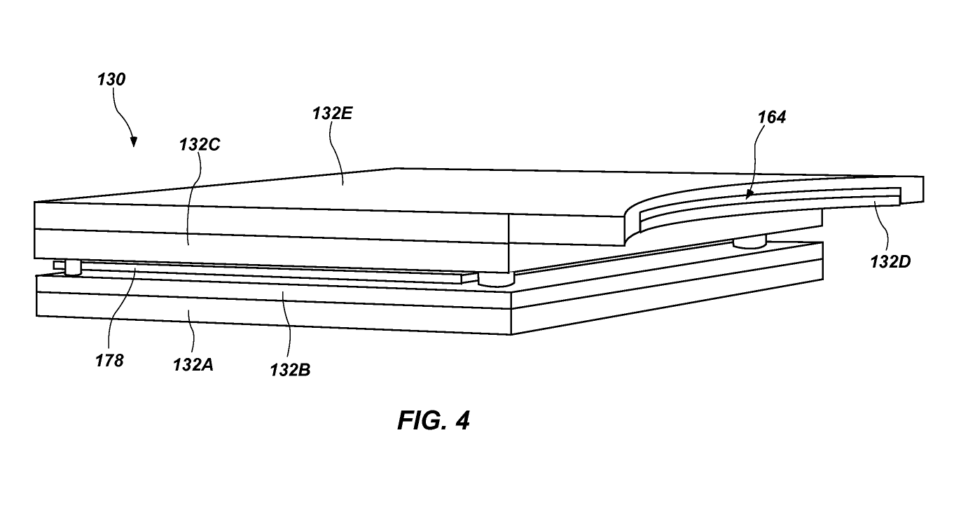

The outlet 164 is configured to output one or more precursor gases from the furnace 130 into the interior region within the reaction chamber 102. FIG. 4 is a perspective view of the furnace 130, and illustrates the outlet 164. As shown in FIG. 4, the outlet 164 may have a rectangular cross-sectional shape, which may assist in preserving laminar flow of the precursor gas or gases being injected out from the furnace 130 and into the interior region within the reaction chamber 102. The outlet 164 may be sized and configured to output a sheet of flowing precursor gas in a transverse direction over an upper surface 168 of the substrate support structure 114. As shown in FIG. 4, the end surface 180 of the fourth generally plate-shaped structure 132D and the end surface 182 of the fifth generally plate-shaped structure 132E, a gap between which defines the outlet 164 from the chamber 162 as previously discussed, may have a shape that generally matches a shape of a workpiece substrate 116 supported on the substrate support structure 114 and on which a material is to be deposited using the precursor gas or gases flowing out from the furnace 130. For example, in embodiments in which the workpiece substrate 116 comprises a die or wafer having a periphery that is generally circular in shape, the surfaces 180, 182 may have an arcuate shape that generally matches the profile of the outer periphery of the workpiece substrate 116 to be processes. In such a configuration, the distance between the outlet 164 and the outer edge of the workpiece substrate 116 may be generally constant across the outlet 164. In this configuration, the precursor gas or gases flowing out from the outlet 164 are prevented from mixing with other precursor gases within the reaction chamber 102 until they are located in the vicinity of the surface of the workpiece substrate 116 on which material is to be deposited by the precursor gases, and avoiding unwanted deposition of material on components of the deposition system 100.

Referring again to FIG. 1, the precursor gas flow path through the furnace 130, as defined through the chamber 134, the chamber 150, and the chamber 162, may have a minimum flow path distance of at least about twelve (12) inches. In the example embodiment of FIGS. 1-3, the flow path distance is about twelve (12) inches for each of the eight (8) serpentine leg sections.

Also, the deposition system 100 may be configured such that the one or more precursor gases caused to flow through the one or more flow paths through the furnace 130 have a residence time within the furnace of at least about 0.2 seconds (e.g., about 0.48 seconds), or even several seconds or more.

Referring again to FIG. 1, the heating elements 118 may comprise a first group 170 of heating elements 118 and a second group 172 of heating elements 118. The first group 170 of heating elements 118 may be located and configured for imparting thermal energy to the furnace 130 and heating the precursor gas therein. For example, the first group 170 of heating elements 118 may be located below the reaction chamber 102 under the furnace 130, as shown in FIG. 1. In additional embodiments, the first group 170 of heating elements 118 may be located above the reaction chamber 102 over the furnace 130, or may include both heating elements 118 located below the reaction chamber 102 under the furnace 130 and heating elements located above the reaction chamber 102 over the furnace 130. The second group 172 of heating elements 118 may be located and configured for imparting thermal energy to the substrate support structure 114 and any workpiece substrate supported thereon. For example, the second group 172 of heating elements 118 may be located below the reaction chamber 102 under the substrate support structure 114, as shown in FIG. 1. In additional embodiments, the second group 172 of heating elements 118 may be located above the reaction chamber 102 over the substrate support structure 114, or may include both heating elements 118 located below the reaction chamber 102 under the substrate support structure 114 and heating elements located above the reaction chamber 102 over the substrate support structure 114.

The first group 170 of heating elements 118 may be separated from the second group 172 of heating elements 118 by a thermally reflective or thermally insulating barrier 174. By way of example and not limitation, such a barrier 174 may comprise a gold-plated metal plate located between the first group 170 of heating elements 118 and the second group 172 of heating elements 118. The metal plate may be oriented to allow independently controlled heating of the furnace 130 (by the first group 170 of heating elements 118) and the substrate support structure 114 (by the second group 172 of heating elements 118). In other words, the barrier 174 may be located and oriented to reduce or prevent heating of the substrate support structure 114 by the first group 170 of heating elements 118, and to reduce or prevent heating of the furnace 130 by the second group 172 of heating elements 118.

The first group 170 of heating elements 118 may comprise a plurality of rows of heating elements 118, which may be controlled independently from one another. In other words, the thermal energy emitted by each row of heating elements 118 may be independently controllable. The rows may be oriented transverse to the direction of the net flow of gas through the reaction chamber 102, which is the direction extending from left to right from the perspective of FIG. 1. Thus, the independently controlled rows of heating elements 118 may be used to provide a selected thermal gradient across the furnace 130, if so desired. Similarly, the second group 172 of heating elements 118 also may comprise a plurality of rows of heating elements 118, which may be controlled independently from one another. Thus, a selected thermal gradient also may be provided across the substrate support structure 114, if so desired.

Optionally, passive heat transfer structures (e.g., structures comprising materials that behave similarly to a black body) may be located adjacent or proximate to at least a portion of the precursor gas furnace 130 within the reaction chamber 102 to improve transfer of heat to the precursor gases within the furnace 130.

Passive heat transfer structures (e.g., structures comprising materials that behave similarly to a black body) may be provided within the reaction chamber 102 as disclosed in, for example, U.S. Patent Application Publication No. 2009/0214785 A1, which published on Aug. 27, 2009 in the name of Arena et al., the entire disclosure of which is incorporated herein by reference. By way of example and not limitation, the precursor gas furnace 130 may include a passive heat transfer plate 178, which may be located between the second plate-shaped structure 132B and the third plate-shaped structure 132C, as shown in FIG. 2. Such a passive heat transfer plate 178 may improve the transfer of heat provided by the heating elements 118 to the precursor gas within the furnace 130, and may improve the homogeneity and consistency of the temperature within the furnace 130. The passive heat transfer plate 178 may comprise a material with high emissivity values (close to unity) (black body materials) that is also capable of withstanding the high temperature, corrosive environment that may be encountered within the reaction chamber 102. Such materials may include, for example, aluminum nitride (AlN), silicon carbide (SiC), and boron carbide (B₄C), which have emissivity values of 0.98, 0.92, and 0.92, respectively. Thus, the passive heat transfer plate 178 may absorb thermal energy emitted by the heating elements 118, and reemit the thermal energy into the furnace 130 and the precursor gas or gases therein.

With continued reference to FIG. 1, the venting and loading subassembly 112 may comprise a vacuum chamber 184 into which gases flowing through the reaction chamber 102 are drawn by the vacuum and vented out from the reaction chamber 102. As shown in FIG. 1, the vacuum chamber 184 may be located below the reaction chamber 102.

The venting and loading subassembly 112 may further comprise a purge gas curtain device 186 that is configured and oriented to provide a generally planar curtain of flowing purge gas, which flows out from the purge gas curtain device 186 and into the vacuum chamber 184. The venting and loading subassembly 112 also may include a gate 188, which may be selectively opened for loading and/or unloading workpiece substrates 116 from the substrate support structure 114, and selectively closed for processing of the workpiece substrates 116 using the deposition system 100. The purge gas curtain emitted by the purge gas curtain device 186 may reduce or prevent parasitic deposition of materials upon the gate 188 during deposition processes.

Gaseous byproducts, carrier gases, and any excess precursor gases may be exhausted out from the reaction chamber 102 through the venting and loading subassembly 112.

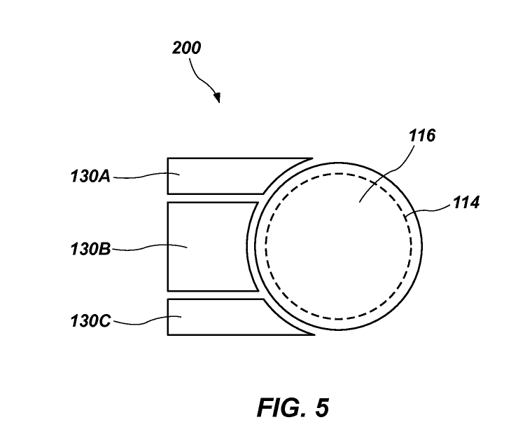

FIG. 5 is a schematic diagram illustrating a plan view of another embodiment of a deposition system 200 that is similar to the deposition system 100 of FIG. 1, but which includes three precursor gas furnaces 130A, 130B, 130C located within an interior region of the reaction chamber 102. Thus, each of the precursor gas furnaces 130A, 130B, 130C may be used for injecting the same or different precursor gases into the reaction chamber 102. By way of example and not limitation, the precursor gas furnace 130B may be used to inject GaCl₃ into the reaction chamber 102, the precursor gas furnace 130A may also be used to inject GaCl₃ into the reaction chamber 102, and the precursor gas furnace 130C may also be used to inject GaCl₃ into the reaction chamber 102. As another example, the precursor gas furnace 130B may be used to inject GaCl₃ into the reaction chamber 102, the precursor gas furnace 130A may be used to inject InCl₃ into the reaction chamber 102, and the precursor gas furnace 130C may be used to inject AlCl₃ into the reaction chamber 102. Optionally, a group III element precursor gas may be injected into the reaction chamber 102 using the precursor gas furnace 130B for deposition of a III-V semiconductor material, and the precursor gas furnaces 130A, 130C may be used to inject one or more precursor gases used for depositing one or more dopant elements into the III-V semiconductor material.

Embodiments of depositions systems as described herein, such as the depositions system 100 of FIG. 1 and the deposition system 200 of FIG. 5 may enable the introduction of relatively large quantities of high temperature precursor gases into the reaction chamber 102 while maintaining the precursor gases spatially separated from one another until the gases are located in the immediate vicinity of the workpiece substrate 116 onto which material is to be deposited, which may improve the efficiency in the utilization of the precursor gases.

Embodiments of depositions systems as described herein, such as the depositions system 100 of FIG. 1 and the deposition system 200 of FIG. 5, may be used to deposit semiconductor material on a workpiece substrate 116 in accordance with further embodiments of the disclosure.

Referring to FIG. 1, a group III element precursor gas and a group V element precursor gas may be caused to flow separately into the reaction chamber 102 through different conduits of the gas inflow conduits 120A-120E. The group III element precursor gas may be caused to flow through at least one precursor gas flow path extending through the precursor gas furnace 130 disposed within the reaction chamber 102 to heat the group III element precursor gas.

After heating the group III element precursor gas within the furnace 130, the group V element precursor gas and the group III element precursor gas may be mixed together within the reaction chamber 102 over the workpiece substrate 116. The surface of the workpiece substrate 116 may be exposed to the mixture of the group V element precursor gas and the group III element precursor gas to form a III-V semiconductor material on the surface of the workpiece substrate 116.

As previously mentioned, the flow path through which the group III element precursor gas is caused to flow may include at least one serpentine configuration (e.g., the configuration of the flow paths within the chamber 134), and at least one section configured to provide laminar flow of the group III element precursor gas (e.g., the configurations of the flow paths within the chamber 150 and the chamber 162). The group III element precursor gas may be caused to flow out from the at least one section configured to provide laminar flow and into an interior region within the reaction chamber 102 outside the furnace 130. The group III element precursor gas may flow out from the furnace 130 in the form of a sheet of the group III element precursor gas in a transverse direction over the upper surface of the workpiece substrate 116, as previously described herein.

The group III element precursor gas may comprise one or more of GaCl₃, InCl₃, and AlCl₃. In such embodiments, the heating of the group III element precursor gas may result in decomposition of at least one of GaCl₃, InCl₃, and AlCl₃ to form at least one of GaCl, InCl, AlCl, and a chlorinated species (e.g., HCl).

Additional non-limiting example embodiments of the invention are described below.

### Embodiment 1

A deposition system, comprising: an at least substantially enclosed reaction chamber defined by a top wall, a bottom wall, and at least one side wall; a susceptor disposed at least partially within the reaction chamber and configured to support a substrate within the reaction chamber; and a gas input system for injecting one or more precursor gases into the reaction chamber, the gas input system comprising at least one precursor gas furnace disposed within the reaction chamber, at least one precursor gas flow path extending through the at least one precursor gas furnace.

### Embodiment 2

The deposition system of Embodiment 1, wherein the at least one precursor gas flow path extending through the at least one precursor gas furnace includes at least one section having a serpentine configuration.

### Embodiment 3

The deposition system of Embodiment 1 or Embodiment 2, wherein the at least one precursor gas flow path has at least one section configured to provide laminar flow of one or more precursor gases caused to flow through the at least one flow path.

### Embodiment 4

The deposition system of Embodiment 3, wherein the at least one section configured to provide laminar flow includes an outlet configured to output one or more precursor gases into an interior region within the reaction chamber.

### Embodiment 5

The deposition system of Embodiment 4, wherein the outlet has a rectangular cross-sectional shape.

### Embodiment 6

The deposition system of Embodiment 4, wherein the outlet is sized and configured to output a sheet of flowing precursor gas in a transverse direction over an upper surface of the susceptor.

### Embodiment 7

The deposition system of any one of Embodiments 1 through 6, wherein the at least one precursor gas flow path has a minimum flow path distance of at least about twelve inches.

### Embodiment 8

The deposition system of any one of Embodiments 1 through 7, wherein the deposition system is configured such that one or more precursor gases caused to flow through the at least one precursor gas flow path have a residence time within the at least one precursor gas furnace of at least about 0.2 seconds.

### Embodiment 9

The deposition system of any one of Embodiments 1 through 8, further comprising at least one heating element configured to impart thermal energy to the at least one precursor gas furnace.

### Embodiment 10

The deposition system of any one of Embodiments 1 through 9, wherein the at least one precursor gas furnace comprises at least two generally planar plates attached together and configured to define at least a portion of the at least one precursor gas flow path therebetween.

### Embodiment 11

The deposition system of any one of Embodiments 1 through 10, wherein the at least one precursor gas furnace comprises two or more precursor gas furnaces.

### Embodiment 12

The deposition system of any one of Embodiments 1 through 11, further comprising: at least one precursor gas source; and at least one conduit configured to carry a precursor gas from the precursor gas source to the at least one precursor gas furnace within the reaction chamber.

### Embodiment 13

The deposition system of Embodiment 12, wherein the at least one precursor gas source comprises a source of at least one of GaCl₃, InCl₃, and AlCl₃.

### Embodiment 14

A method of depositing a semiconductor material, comprising: separately flowing a group III element precursor gas and a group V element precursor gas into a reaction chamber; flowing the group III element precursor gas through at least one precursor gas flow path extending through at least one precursor gas furnace disposed within the reaction chamber to heat the group III element precursor gas; after heating the group III element precursor gas within the at least one precursor gas furnace within the reaction chamber, mixing the group V element precursor gas and the group III element precursor gas within the reaction chamber over a substrate; and exposing a surface of the substrate to the mixture of the group V element precursor gas and the group III element precursor gas to form a III-V semiconductor material on the surface of the substrate.

### Embodiment 15

The method of Embodiment 14, wherein heating the group 111 element precursor gas comprises decomposing at least one of GaCl₃, InCl₃, and AlCl₃ to form at least one of GaCl, InCl, and AlCl and a chlorinated species.

### Embodiment 16

The method of Embodiment 15, wherein decomposing at least one of GaCl₃, InCl₃, and AlCl₃ to form at least one of GaCl, InCl, and AlCl and a chlorinated species comprises decomposing GaCl₃ to form GaCl and a chlorinated species.

### Embodiment 17

The method of any one of Embodiments 14 through 16, wherein the at least one precursor gas flow path includes at least one section having a serpentine configuration, and wherein flowing the group III element precursor gas through at least one precursor gas flow path comprises flowing the group III element precursor gas through the at least one section of the at least one precursor gas flow path having the serpentine configuration.

### Embodiment 18

The method of any one of Embodiments 14 through 17, wherein the at least one precursor gas flow path has at least one section configured to provide laminar flow of the group III element precursor gas, and wherein flowing the group III element precursor gas through at least one precursor gas flow path comprises flowing the group III element precursor gas through the at least one section configured to provide laminar flow of the group III element precursor gas.

### Embodiment 19

The method of Embodiment 18, further comprising flowing the group III element precursor gas out from the at least one section configured to provide laminar flow of the group III element precursor gas and into an interior region within the reaction chamber.

### Embodiment 20

The method of Embodiment 19, wherein flowing the group III element precursor gas out from the at least one section configured to provide laminar flow of the group III element precursor gas further comprises forming a sheet of the group III element precursor gas generally flowing in a transverse direction over the upper surface of the substrate.

### Embodiment 21

The method of any one of Embodiments 14 through 20, wherein flowing the group III element precursor gas through the at least one precursor gas flow path extending through at least one precursor gas furnace comprises flowing the group III element precursor gas through a minimum distance of at least about twelve inches within the at least one precursor gas furnace.

### Embodiment 22

The method of any one of Embodiments 14 through 21, wherein flowing the group III element precursor gas through the at least one precursor gas flow path extending through at least one precursor gas furnace comprises causing the group III element precursor gas to reside within the at least one precursor gas furnace for at least about 0.2 seconds.

### Embodiment 23

The method of any one of Embodiments 14 through 22, further comprising imparting thermal energy to the at least one precursor gas furnace using at least one heating element.

The embodiments of the invention described above do not limit the scope the invention, since these embodiments are merely examples of embodiments of the invention, which is defined by the scope of the appended claims and their legal equivalents. Any equivalent embodiments are intended to be within the scope of this invention. Indeed, various modifications of the invention, in addition to those shown and described herein, such as alternate useful combinations of the elements described, will become apparent to those skilled in the art from the description. Such modifications are also intended to fall within the scope of the appended claims.

What is claimed is:

1. A deposition system, comprising:
an at least substantially enclosed reaction chamber defined by a top wall, a bottom wall, and at least one side wall;
a susceptor disposed at least partially within the reaction chamber and configured to support a substrate within the reaction chamber; and
a gas input system for injecting one or more precursor gases into the reaction chamber, the gas input system comprising at least one precursor gas furnace disposed within the reaction chamber, at least one precursor gas flow path extending through the at least one precursor gas furnace.

2. The deposition system of claim 1, wherein the at least one precursor gas flow path extending through the at least one precursor gas furnace includes at least one section having a serpentine configuration.

3. The deposition system of claim 2, wherein the at least one precursor gas flow path has at least one section configured to provide laminar flow of one or more precursor gases caused to flow through the at least one flow path.

4. The deposition system of claim 3, wherein the at least one section configured to provide laminar flow includes an outlet configured to output one or more precursor gases into an interior region within the reaction chamber.

5. The deposition system of claim 4, wherein the outlet has a rectangular cross-sectional shape.

6. The deposition system of claim 4, wherein the outlet is sized and configured to output a sheet of flowing precursor gas in a transverse direction over an upper surface of the susceptor.

7. The deposition system of claim 1, wherein the at least one precursor gas flow path has a minimum flow path distance of at least about twelve inches.

8. The deposition system of claim 1, wherein the deposition system is configured such that one or more precursor gases caused to flow through the at least one precursor gas flow path have a residence time within the at least one precursor gas furnace of at least about 0.2 seconds.

9. The deposition system of claim 1, further comprising at least one heating element configured to impart thermal energy to the at least one precursor gas furnace.

10. The deposition system of claim 1, wherein the at least one precursor gas furnace comprises at least two generally planar plates attached together and configured to define at least a portion of the at least one precursor gas flow path therebetween.

11. The deposition system of claim 1, wherein the at least one precursor gas furnace comprises two or more precursor gas furnaces.

12. The deposition system of claim 1, further comprising:
at least one precursor gas source; and
at least one conduit configured to carry a precursor gas from the precursor gas source to the at least one precursor gas furnace within the reaction chamber.

13. The deposition system of claim 12, wherein the at least one precursor gas source comprises a source of at least one of GaCl₃, InCl₃, and AlCl₃.

14. A method of depositing a semiconductor material, comprising:
separately flowing a group III element precursor gas and a group V element precursor gas into a reaction chamber;
flowing the group III element precursor gas through at least one precursor gas flow path extending through at least one precursor gas furnace disposed within the reaction chamber to heat the group III element precursor gas;
after heating the group III element precursor gas within the at least one precursor gas furnace within the reaction chamber, mixing the group V element precursor gas and the group III element precursor gas within the reaction chamber over a substrate; and
exposing a surface of the substrate to the mixture of the group V element precursor gas and the group III element precursor gas to form a III-V semiconductor material on the surface of the substrate.

15. The method of claim 14, wherein heating the group III element precursor gas comprises decomposing at least one of GaCl₃, InCl₃, and AlCl₃ to form at least one of GaCl, InCl, and AlCl and a chlorinated species.

16. The method of claim 15, wherein decomposing at least one of GaCl₃, InCl₃, and AlCl₃ to form at least one of GaCl, InCl, and AlCl and a chlorinated species comprises decomposing GaCl₃ to form GaCl and a chlorinated species.

17. The method of claim 14, wherein the at least one precursor gas flow path includes at least one section having a serpentine configuration, and wherein flowing the group III element precursor gas through at least one precursor gas flow path comprises flowing the group III element precursor gas through the at least one section of the at least one precursor gas flow path having the serpentine configuration.

18. The method of claim 14, wherein the at least one precursor gas flow path has at least one section configured to provide laminar flow of the group III element precursor gas, and wherein flowing the group III element precursor gas through at least one precursor gas flow path comprises flowing the group III element precursor gas through the at least one section configured to provide laminar flow of the group III element precursor gas.

19. The method of claim 18, further comprising flowing the group III element precursor gas out from the at least one section configured to provide laminar flow of the group III element precursor gas and into an interior region within the reaction chamber.

20. The method of claim 19, wherein flowing the group III element precursor gas out from the at least one section configured to provide laminar flow of the group III element precursor gas further comprises forming a sheet of the group III element precursor gas generally flowing in a transverse direction over the upper surface of the substrate.

21. The method of claim 14, wherein flowing the group III element precursor gas through the at least one precursor gas flow path extending through at least one precursor gas furnace comprises flowing the group III element precursor gas through a minimum distance of at least about twelve inches within the at least one precursor gas furnace.

22. The method of claim 14, wherein flowing the group III element precursor gas through the at least one precursor gas flow path extending through at least one precursor gas furnace comprises causing the group III element precursor gas to reside within the at least one precursor gas furnace for at least about 0.2 seconds.

23. The method of claim 14, further comprising imparting thermal energy to the at least one precursor gas furnace using at least one heating element.
